(19) United States
(12) Patent Application Publication
(10) Pub. No.: US 2024/0213349 A1
(43) Pub. Date: Jun. 27, 2024

(54) ELECTRONIC DEVICE INCLUDING FERROELECTRIC MATERIAL AND ELECTRONIC APPARATUS INCLUDING THE ELECTRONIC DEVICE

(71) Applicant: Samsung Electronics Co., Ltd., Suwon-si (KR)

(72) Inventors: Sanghyun JO, Suwon-si (KR); Yunseong LEE, Osan-si (KR); Hyangsook LEE, Suwon-si (KR); Dukhyun CHOE, Suwon-si (KR); Jinseong HEO, Suwon-si (KR)

(73) Assignee: Samsung Electronics Co., Ltd., Suwon-si (KR)

(21) Appl. No.: 18/396,258

(22) Filed: Dec. 26, 2023

(30) Foreign Application Priority Data
Dec. 27, 2022 (KR) 10-2022-0185904

(51) Int. Cl. H01L 29/51; H01L 21/28; H01L 29/423; H01L 29/78; H10B 51/20; H10B 53/20

(52) U.S. Cl. CPC H01L 29/516; H01L 29/40111; H01L 29/42392; H01L 29/78391; H01L 29/7851; H10B 51/20; H10B 53/20

(57) ABSTRACT

An electronic device and an electronic apparatus including the electronic device are provided. The electronic device includes a conductive material layer, and a ferroelectric layer covering the conductive material layer. The ferroelectric layer includes a first oxide layer including a first component, and a second oxide layer including hafnium and a second component and having a thickness that is twice or more than a thickness of the first oxide layer.

### CROSS-REFERENCE TO RELATED APPLICATION

This application is based on and claims priority under 35 U.S.C. § 119 to Korean Patent Application No. 10-2022-0185904, filed on Dec. 27, 2022, in the Korean Intellectual Property Office, the disclosure of which is incorporated by reference herein in its entirety.

### BACKGROUND

### 1. Field

The disclosure relates to an electronic device including a ferroelectric material and an electronic apparatus including the electronic device.

### 2. Description of the Related Art

As the degree of integration of electronic apparatuses, such as memory or logic circuits, has increased, electronic devices in such electronic apparatuses have become more miniaturized. Accordingly, there is an increasing demand for miniaturization and low power consumption of electronic devices such as transistors and capacitors. However, because a capacitance of an electronic device is proportional to its area, the capacitance may decrease as the electronic device is miniaturized. As a thickness of a dielectric is reduced to increase a capacitance, leakage current may increase. Accordingly, there has been an increase in demand for dielectric materials having a high dielectric constant (high-K) to be used in electronic devices.

Recently, new low-power devices using negative capacitance characteristics of ferroelectric materials have been proposed. To implement such a low-power device, it is required to form a ferroelectric thin film for each device and improve a negative capacitance effect by using the ferroelectric thin film.

### SUMMARY

Provided is an electronic device with an improved negative capacitance effect by including a ferroelectric material.

Provided is an electronic apparatus including an electronic device including a ferroelectric material.

Additional aspects will be set forth in part in the description which follows and, in part, will be apparent from the description, or may be learned by practice of the presented embodiments.

According to an aspect of the disclosure, an electronic device includes a conductive material layer, a ferroelectric layer covering the conductive material layer and having ferroelectric or antiferroelectric properties, and an electrode layer covering the ferroelectric layer, wherein the ferroelectric layer includes a first oxide layer comprising a first component and having a first thickness, and a second oxide layer comprising hafnium and a second component and having a second thickness that is twice or more the first thickness.

A ratio of the second thickness to the first thickness is 2:1 to 10:1.

The first thickness may be 1 nm or less, and a total thickness of the ferroelectric layer may be 3 nm or less.

The first thickness may be 0.2 nm to 1 nm, and the total thickness of the ferroelectric layer may be 0.5 nm to 3 nm.

A proportion of the second component may be greater than a proportion of the hafnium at a surface of the second oxide layer.

A proportion of the second component may be greater than the proportion of the hafnium in a region of the second oxide layer from the surface to a thickness portion of ⅓ or less.

The first component and the second component may be Zr, the first oxide layer may comprise ZrO2, and the second oxide layer may comprise alternating oxides of Hf and Zr.

The second oxide layer may comprise alternating oxides of Hf and the second component, and a proportion of the second component may be greater than a proportion of the hafnium at a surface of the second oxide layer.

The second oxide layer may be formed by alternately and repeatedly depositing the hafnium oxide and the oxide of the second component in one cycle or in multiple cycles.

The first component and the second component may each be at least one of Zr, Si, Al, Y, La, Gd, or Sr.

The first component and the second component may be the same, and a composition ratio of an oxide of the first component to an oxide of the hafnium may be greater than 1 in the ferroelectric layer.

The first oxide layer may include ZrO2, and the second oxide layer may comprise alternating oxides of the hafnium and Zr.

The second oxide layer may be formed by alternately and repeatedly depositing a hafnium oxide and an oxide of the second component, wherein a surface of the second oxide layer is terminated with an oxide of one of the hafnium or the second component.

Layers may be stacked in an order of the first oxide layer, the second oxide layer, and the electrode layer, or an order of the second oxide layer, the first oxide layer, and the electrode layer, wherein ferroelectric crystallization of the ferroelectric layer is performed by heat treatment before and/or after the electrode layer is formed.

The electronic device may further include a dielectric layer, that is not ferroelectric, between at least one of the conductive material layer and the ferroelectric layer or the ferroelectric layer and the electrode layer.

The conductive material layer may include a channel, the electrode layer may include a gate electrode, and the electronic device may be a logic or memory device.

The electronic device may be at least one of a fin field-effect transistor (FinFET), a gate-all-around FET (GAAFET), or a multi-bridge channel FET (MBCFET), wherein the electronic device further includes a substrate, and the channel includes a plurality of channel elements extending in a first direction and are least one of spaced apart from a top surface of the substrate or arranged at intervals from each other in a second direction different from the first direction.

The ferroelectric layer may be one of comprises a plurality of the ferroelectric layers disposed to respectively surrounding the plurality of channel elements, and the gate electrode may protrude from the top surface of the substrate to surround the plurality of the ferroelectric layers.

The gate electrode be included in a stacked structure such that a stacked structure includes a plurality of insulating layers and a plurality of the gate electrodes alternately stacked, wherein the electronic device further includes a plurality of channel holes vertically penetrating the stacked structure, wherein the ferroelectric layer and the conductive material layer are concentrically arranged in each of the plurality of channel holes.

According to another aspect of the disclosure, an electronic apparatus includes at least one electronic device, wherein the at least one electronic device includes a conductive material layer, a ferroelectric layer covering the conductive material layer and having ferroelectric or antiferroelectric properties, and an electrode layer covering the ferroelectric layer, wherein the ferroelectric layer includes a first oxide layer including a first component, and a second oxide layer including hafnium and a second component.

### BRIEF DESCRIPTION OF THE DRAWINGS

The above and other aspects, features, and advantages of certain embodiments will be more apparent from the following description taken in conjunction with the accompanying drawings, in which:

FIGS. 1 to 3 are cross-sectional views schematically illustrating electronic devices, according to some example embodiments;

FIG. 4A is a view illustrating a thin film structure of a ferroelectric layer of an electronic device, according to at least one embodiment;

FIGS. 4B to 4D are views illustrating thin film structures of comparative example 1, comparative example 2, and comparative example 3, respectively;

FIG. 5 is a diagram illustrating an equivalent oxide thickness (EOT) change for each ferroelectric thin film structure, in a metal-ferroelectric-insulator-silicon (MOSCAP) structure to which ferroelectric thin film structures of the embodiment of FIG. 4A, comparative example 1 of FIG. 4B, comparative example 2 of FIG. 4C, and comparative example 3 of FIG. 4D are applied;

FIG. 6 is a view illustrating an example of an electronic device having a three-dimensional (3D) structure including a Fin channel, according to at least one embodiment;

FIG. 7 is a view illustrating an example of an electronic device having a 3D structure in which a gate electrode surrounds a channel in all directions, according to at least one embodiment;

FIG. 8 is a cross-sectional view schematically illustrating a gate structure of the electronic device of FIG. 7;

FIG. 9 is a schematic circuit diagram illustrating a memory device including an electronic device array;

FIG. 10 is a perspective view illustrating an electronic device, according to at least one embodiment;

FIG. 11 is an enlarged cross-sectional view illustrating a portion ‘A’ of FIG. 10;

FIGS. 12 and 13 are cross-sectional views schematically illustrating electronic devices, according to embodiments;

FIG. 14 is a view schematically illustrating an example of applying an electronic device, according to at least one embodiment;

FIG. 15 is a schematic block diagram illustrating a display driver integrated circuit (IC) and a display apparatus including the display driver IC, according to at least one embodiment;

FIGS. 16 and 17 are block diagrams illustrating electronic apparatuses, according to embodiments; and

FIGS. 18 and 19 are conceptual diagrams schematically illustrating device architectures applicable to an electronic apparatus, according to at least some embodiments.

### DETAILED DESCRIPTION

Reference will now be made in detail to embodiments, examples of which are illustrated in the accompanying drawings, wherein like reference numerals refer to like elements throughout, and in the drawings, sizes of elements may be exaggerated for clarity and convenience of explanation. In this regard, the present embodiments may have different forms and should not be construed as being limited to the descriptions set forth herein. Accordingly, the embodiments are merely described below, by referring to the figures, to explain aspects, and various modifications may be made from the embodiments. As used herein, the term “and/or” includes any and all combinations of one or more of the associated listed items. Expressions such as “at least one of,” when preceding a list of elements, modify the entire list of elements and do not modify the individual elements of the list.

When a first element is “on˜” or “over” a second element, it may include a case where the first element contacts the second element and is directly located on the top, bottom, left, or right of the second element, and a case where the first element does not contact the second element and is located on the top, bottom, left, or right of the second element with a third element therebetween unless expressly indicated otherwise. For example, it will be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms “a,” “an,” and “the” are intended to include the plural forms as well, unless the context clearly indicates otherwise. When a part “includes” an element, another element may be further included, rather than excluding the existence of the other element, unless otherwise described. When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

The steps of all methods described herein may be performed in any suitable order unless otherwise indicated herein or otherwise clearly contradicted by context, and are not limited to the described order.

Functional elements described herein using terms such as “. . . unit” or “module” indicates a unit for processing at least one function or operation, and may be implemented in processing circuitry such as hardware, software, or in a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. For example, the processing circuitry may include electrical components such as logic gates including at least one of AND gates, OR gates, NAND gates, NOT gates, etc., and/or electronic circuits including said components.

The terms first, second, etc., may be used to describe various components, but the components should not be limited by terms. Terms are used only for the purpose of distinguishing one component from another. When there is an explicit description of the order of operations of the method or there is no description contrary thereto, these operations may be performed in an appropriate order and the order is not necessarily limited to the described order.

Also, lines or members connecting elements illustrated in the drawings are merely illustrative of functional connections and/or physical or circuit connections. In an actual device, the connections between elements may be represented by various functional connections, physical connections, or circuit connections that are replaceable or added.

The use of any and all examples, or exemplary language provided herein, is intended merely to better describe the disclosure and does not pose a limitation on the scope of the disclosure unless otherwise claimed.

When an electric field is applied to a dielectric material, dielectric polarization in which polar molecules are aligned occurs. A degree of polarization is proportional to the electric field. The degree to which the dielectric is polarized in proportion to the applied electric field may be expressed as a permittivity. A permittivity ε of a dielectric material may be often expressed by a relative permittivity εᵣ, which is a ratio of the permittivity to a vacuum permittivity ε₀ and is also called a dielectric constant. Because a permittivity does not deal with an absolute value, the above expressions may be interchangeably used.

Due to a molecular structure of a dielectric material, the permittivity may vary according to a direction of the applied electric field.

In the case of a ferroelectric material exhibiting ferroelectric property, spontaneous polarization is maintained therein as electric dipole moments are aligned without an external electric field applied thereto. For example, even when dielectric polarization is formed by an applied electric field E and then the applied electric field disappears, polarization is not 0 and a certain amount of remnant polarization remains. That is, a ferroelectric material may be applied to various electronic devices such as a non-volatile memory device, a neuromorphic device, a capacitor, and/or the like, because the ferroelectric material has polarization characteristics dependent on a hysteresis of an applied electric field E, generally exhibits a higher permittivity than a paraelectric material, and has remnant polarization even after the applied electric field disappears.

An electronic device according to at least one embodiment may include a ferroelectric layer, and the ferroelectric layer may have ferroelectric properties or antiferroelectric properties. That is, the electronic device according to at least one embodiment may include a ferroelectric layer or an antiferroelectric layer. The ferroelectric layer may include at least 50% of domains having an orthorhombic crystalline phase, and less than 50% of tetragonal crystalline phase, monoclinic, or amorphous domains. The antiferroelectric layer may include at least 50% of domains having a tetragonal crystalline phase, and less than 50% of orthorhombic crystalline phase, monoclinic, or amorphous domains. Because an antiferroelectric material may be changed into a ferroelectric material when a bias is applied, hereinafter, it is considered that a ferroelectric layer is formed to have ferroelectric properties or antiferroelectric properties, and the expression ‘ferroelectric layer’ is considered to mean a ferroelectric layer or an antiferroelectric layer except when explicitly provided in contrast to the other.

The electronic device according to at least one embodiment may include a conductive material layer, a ferroelectric layer covering the conductive material layer, and an electrode layer covering the ferroelectric layer; the ferroelectric layer may include a first oxide layer including a first component, and a second oxide layer including hafnium and a second component. The second oxide layer may have a thickness that is twice or more (for example, twice or more and/or ten times or less) than a thickness of the first oxide layer.

According to at least one embodiment, the first oxide layer may be formed to have a thickness of 1 nm or less, for example, a thickness ranging from about 0.2 nm to about 1 nm, and the ferroelectric layer may be formed to have a thickness of 3 nm or less as a whole, for example, a thickness ranging from about 0.5 nm to about 3 nm.

According to at least one embodiment, the second oxide layer may be formed by alternately and repeatedly depositing a hafnium oxide and an oxide including the second component, and a surface of the second oxide layer may be terminated (or capped) with one of the hafnium oxide and/or the oxide including the second component. The hafnium oxide and the oxide including the second component may be soluble and/or partially soluble, such that the second oxide layer includes a solid solution of the hafnium oxide and the oxide including the second component. For example, according to at least one embodiment, the deposition of the second oxide layer may be terminated with the oxide layer including the second component. In these cases, the second component may be distributed more on the surface of the second oxide layer, and/or an element proportion of the second component may be greater than that the of hafnium (Hf) element from the surface of the second oxide layer compared to a thickness portion, for example, within about ⅓ from the surface of the second oxide layer, For example, in at least some embodiments, the ratio of hafnium to the second component may decrease from the thickness portion to the surface of the second oxide layer.

According to at least one embodiment, the first oxide layer may be formed as a single film layer, and the second oxide layer may be formed as a solid solution layer formed by using a solid solution deposition method, and thus, the ferroelectric layer including the first oxide layer and the second oxide layer may have a laminate structure. The first oxide layer may be formed as a layer having a certain thickness, and the first component of the first oxide layer may be at least one of Zr, Si, Al, Y, La, Gd, and/or Sr. The second oxide layer may be formed by using a solid solution deposition method in which a hafnium oxide (HfO2) and an oxide including the second component are alternately deposited. For example, a hafnium oxide may be deposited by one cycle or multiple cycles of atomic layer deposition through sequential injection of an Hf precursor and an oxidant, and an oxide including the second component may be deposited by one cycle or multiple cycles of atomic layer deposition through sequential injection of a precursor of the second component and an oxidant. The second oxide layer may be formed by alternately depositing the hafnium oxide and the oxide including the second component. According to at least one embodiment, the second component may be at least one of Zr, Si, Al, Y, La, Gd, and/or Sr.

According to at least one embodiment, the first oxide layer may be formed of zirconium oxide (e.g., ZrO2), the second oxide layer may be formed of a solid solution layer formed using a solid solution deposition method in which HfO2 and ZrO2 are alternately deposited in one cycle or multiple cycles, and thus, the ferroelectric layer may have a ZrO2/HZO thin film structure. Because the second oxide layer of the at least one embodiment is formed using a solid solution deposition method, the second oxide layer may be terminated with ZrO2 or HfO2. For example, the second oxide layer may be terminated with ZrO2, and in this case, the Zr element may be distributed more on an upper surface in the second oxide layer, and a proportion of the Zr element may be greater than a proportion of an Hf element in a thickness portion (for example, a portion within about ⅓ from the surface of the second oxide layer). In this case, the ZrO2 layer of the first oxide layer may have a thickness of about 0.2 nm to about 1 nm, a total thickness of the ferroelectric layer may be about 0.5 nm to about 3 nm, and a thickness ratio of the second oxide layer (e.g., the HZO layer) to the first oxide layer (e.g., the ZrO2 layer) may be 2:1 to 10:1.

In the electronic device according to at least one embodiment, a conductive material layer may be a channel or another electrode layer.

For example, the electronic device according to at least one embodiment may be a logic transistor or a memory transistor, and in these cases, the conductive material layer may be a channel, a ferroelectric layer may be a gate insulating film, and an electrode layer may be a gate electrode. In this case, the ferroelectric layer forming the gate insulating film may include a first oxide layer including a first component and a second oxide layer including hafnium and a second component and formed by using a solid solution deposition method. A dielectric layer that is not ferroelectric may be further located between the conductive material layer and the ferroelectric layer and/or between the ferroelectric layer and the electrode layer. In this case, the dielectric layer may include both crystalline and amorphous states. The electronic device according to at least one embodiment may be implemented as a memory device or a logic device.

Also, the electronic device according to at least one embodiment may include another electrode layer as a conductive material layer, and may be implemented as a capacitor or a part of a ferroelectric memory or an electronic circuit using the capacitor.

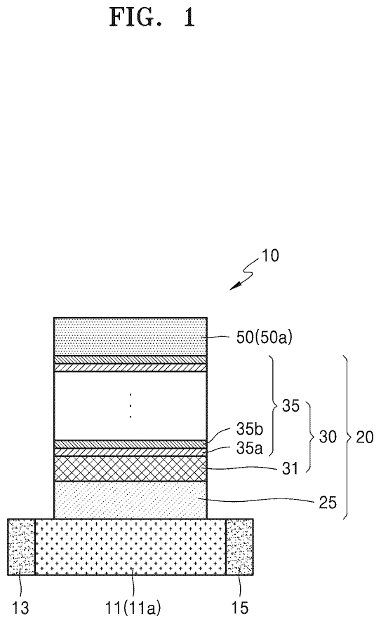

FIG. 1 is a cross-sectional view schematically illustrating an electronic device 10, according to at least one embodiment. FIG. 1 illustrates an example where the electronic device 10 according to at least one embodiment is implemented as a logic transistor or a memory transistor.

Referring to FIG. 1, the electronic device 10 includes a channel 11 as a conductive material layer 11a, a gate insulating film 20 including a ferroelectric layer 30 and covering the channel 11, and a gate electrode 50 as an electrode layer 50a on the gate insulating film 20. The electronic device 10 according to at least one embodiment includes a first source/drain region 13 and a second source/drain region 15 electrically connected to both ends of the channel 11. One of the first source/drain region 13 and the second source/drain region 15 may be a source region S, and the other may be a drain region D.

The electronic device 10 according to at least one embodiment may be implemented as a memory device having two or more threshold voltages. Also, the ferroelectric layer 30 in the electronic device 10 according to at least one embodiment may have a negative capacitance (NC) according to an applied voltage range, and may be implemented as a logic device.

The channel 11 May be formed as a substrate base, and/or may be implemented as a separate material layer. For example, when the channel 11 is formed as a substrate base, the channel 11 may include an element or compound semiconductor, such as silicon (Si), germanium (Ge), silicon germanium (SiGe), silicon carbide (SiC), a group III-V semiconductor material (such as gallium arsenide (GaAs), indium arsenide (InAs), or indium phosphide (InP)), and/or the like. Also, when the channel 11 is implemented as a separate material layer, the channel 11 May include Si, Ge, SiGe, SiC, a group III-V semiconductor material, an oxide semiconductor, a nitride semiconductor, an oxynitride semiconductor, a two-dimensional (2D) material, quantum dots, an organic semiconductor, and/or the like. For example, according to at least one embodiment, the oxide semiconductor may include a transparent semiconductor such as InGaZnO (and/or the like). The 2D material may include a transition metal dichalcogenide (TMD), graphene, and/or the like. The TMD may include a compound of a transition metal and a chalcogen element. For example, the TMD may include MoS₂, MoSe₂, MoTe₂, WS₂, WSe₂, WTe₂, ZrS₂, ZrSe₂, HfS₂, HfSe₂, NbSe₂, or ReSe₂. The quantum dots may include colloidal quantum dots (QDs) and/or a nanocrystal structure.

The first source/drain region 13 may be formed on a side of the channel 11, and the second source/drain region 15 may be formed on the other side of the channel 11. When the channel 11 is formed as a substrate base, the first source/drain region 13, the second source/drain region 15, and the channel 11 May be formed by injecting impurities into different regions of a semiconductor substrate, and may include a substrate material as a base material. For example, the channel 11 may be a Si channel and the first source/drain region 13 and the second source/drain region 15 may include Si with impurities as dopants. When the channel 11 is implemented as a separate material layer, the first source/drain region 13 and the second source/drain region 15 may be formed of a conductive material. For example, the source 13 and the drain 15 may include a metal, a metal compound, a conductive polymer, and/or the like.

In the electronic device 10 according to at least one embodiment, the gate insulating film 20 may include the ferroelectric layer 30.

The ferroelectric layer 30 May include a first oxide layer 31 including a first component, and a second oxide layer 35 including hafnium and a second component.

The first oxide layer 31 may be formed as a single film layer having a first thickness, and the first component of the first oxide layer 31 may be at least one of Zr, Si, Al, Y, La, Gd, and/or Sr. For example, the first oxide layer 31 may be formed of a ZrO2 layer, but the examples are not limited thereto.

The second oxide layer 35 may include hafnium (Hf) and the second component. The second component may be at least one of Zr, Si, Al, Y, La, Gd, and/or Sr. For example, each of the first component of the first oxide layer 31 and the second component of the second oxide layer 35 may be at least one selected from among Zr, Si, Al, Y, La, Gd, and/or Sr, and the second component may be the same as or different from the first component.

The second oxide layer 35 may include a structure in which a hafnium oxide (HfO2) layer 35a and an oxide layer 35b including the second component are alternately and repeatedly deposited. When the second component is expressed as ‘A’, the second oxide layer 35a may be formed of HfₓA₁₋ₓO₂ (HAO), for example, HfₓZr₁₋ₓO₂ (HZO), and a surface of the second oxide layer 35 may be terminated with any one of a hafnium oxide and an oxide including the second component. For example, the second oxide layer 35 may be terminated with an oxide layer including the second component, and thus, the second component may be more distributed on the surface of the second oxide layer 35, and a proportion of the second component may be greater than a proportion of a hafnium (Hf) element to the thickness portion (for example, a portion within about ⅓ from the surface of the second oxide layer 35). The alternating hafnium oxide layer 35a and the oxide layer 35b including the second component are illustrated as distinct layers, but the examples are not limited thereto. For example, the hafnium oxide layer 35a and the oxide layer 35b including the second component may comprise soluble and/or partially soluble oxides, such that hafnium and/or the second component diffuses between the hafnium oxide layer 35a and the oxide layer 35b including the second component, and the barrier therebetween may be indistinct. For example, if the case wherein the second oxide layer 35 was terminated with the second component, the second component may be included at a higher concentration, compared to the hafnium, at the upper surface of the second oxide layer 35. In at least some embodiments, the first oxide layer 31 may be formed to a thickness of about 0.2 nm to about 1 nm. A total thickness of the ferroelectric layer 30 may be about 0.5 nm to about 3 nm. Also, the second oxide layer 35 may be formed to have a thickness that is twice or more than that of the first oxide layer 31, for example, twice or more and/or 10 times or less than that of the first oxide layer 31. For example, a thickness ratio of the second oxide layer 35 to the first oxide layer 31 may be 2:1 to 10:1.

The second component of the second oxide layer 35 and the first component of the first oxide layer 31 may be different from or the same as each other. For example, in at least one embodiment, both the first component and the second component of the first oxide layer 31 and the second oxide layer 35 may be Zr. That is, in at least one embodiment, the first oxide layer 31 may be formed as a ZrO2 layer, the second oxide layer 35 may be formed of HfₓZr₁₋ₓO₂ (HZO), and the surface of the second oxide layer 35 may be terminated with one of HfO2 and ZrO2.

For example, the second oxide layer 35 may be terminated with, ZrO2, and in this case, a Zr element may be more distributed on the surface of the second oxide layer 35, and a proportion of the Zr element may be greater than a proportion of an Hf element at a thickness portion (for example, within about ⅓ from the surface of the second oxide layer 35). The ZrO2 layer of the first oxide layer 31 may be formed to a thickness of about 1 nm or less, for example, a thickness of about 0.2 nm to about 1 nm, and a total thickness of the ferroelectric layer 30 may be about 3 nm or less, for example, about 0.5 nm to about 3 nm. Also, a thickness ratio of HZO to ZrO2 may be 2:1 to 10:1.

Although the second oxide layer 35 starts with the hafnium oxide (HfO2) layer 35a and ends with the oxide layer 35b including the second component in FIG. 1 and the following drawings, the examples are not limited thereto.

The second oxide layer 35 may be formed by using a solid solution deposition method. For example, the second oxide layer 35 may be formed by alternately depositing the hafnium oxide layer 35a and the oxide layer 35b including the second component in one cycle or multiple cycles. For example, the hafnium oxide layer 35a may be formed by one cycle or multiple cycles of atomic layer deposition through sequential injection of an Hf precursor and an oxidant, and the oxide layer 35b including the second component may be deposited by one cycle or multiple cycles of atomic layer deposition through sequential injection of a precursor of the second component and an oxidant. The second oxide layer 35 may be formed by alternately depositing the hafnium oxide layer 35a and the oxide layer 35b including the second component in one cycle or multiple cycles. In these cases, the second component may be at least one of Zr, Si, Al, Y, La, Gd, and/or Sr.

That is, doped hafnium oxide may be produced by using a solid solution deposition method of alternately depositing a hafnium oxide layer and a dopant oxide layer. For example, in the case of Hf_{0.5}Zr_{0.5}O₂ (HZO) that is a doped hafnia ferroelectric thin film, the thin film may be formed by alternately depositing HfO2 and ZrO2, for example, one layer or multiple layers, in the same number of cycles.

As such, in the ferroelectric layer 30, the first oxide layer 31 including the first component may be formed as a single film layer having a certain thickness, and the second oxide layer 35 may be formed by alternately depositing HfO2 and a dopant oxide (an oxide including the second component), for example, one layer or multiple layers, by using a solid solution deposition method. In this case, a dopant (that is the second component) may be at least one selected from among Zr, Si, Al, Y, La, Gd, and Sr, and may be the same as or different from the first component of the first oxide layer 31.

For example, according to the electronic device 10 according to at least one embodiment, the first component of the first oxide layer 31 and the second component of the second oxide layer 35 constituting the ferroelectric layer 30 may be the same. In this case, because the first oxide layer 31 is a single film layer formed of an oxide including the first component and the second oxide layer 35 is a solid solution layer formed by repeatedly stacking an oxide including the first component/a hafnium oxide, the ferroelectric layer 30 including the first oxide layer 31 and the second oxide layer 35 may have a laminate structure, and a composition ratio of the oxide including the first component/the hafnium oxide in the ferroelectric layer 30 may be greater than 1.

For example, when both the first and second components are Zr, the first oxide layer 31 may be a single film layer formed of ZrO2, and the second oxide layer 35 may be an HZO layer formed by using a solid solution deposition method of alternately depositing an HfO2 layer and a ZrO2 layer in one cycle or multiple cycles. The second oxide layer 35 may be terminated with ZrO2 or HfO2. In this case, in the ferroelectric layer 30, a composition ratio of the oxide including the first component/the hafnium oxide (e.g., a composition ratio of ZrO2/HfO2) may be greater than 1.

Layers of the electronic device 10 according to at least one embodiment may be stacked in the order of the first oxide layer 31, the second oxide layer 35, and the gate electrode 50, or in the order of the second oxide layer 35, the first oxide layer 31, and the gate electrode 50. FIG. 1 illustrates an example where layers of the electronic device 10 are stacked in the order of the first oxide layer 31, the second oxide layer 35, and the gate electrode 50.

For example, when the first oxide layer 31 is formed of ZrO2 and the second oxide layer 35 is an HZO layer formed by using a solid solution deposition method of repeatedly stacking HfO2 and ZrO2, the ferroelectric layer 30 may have a ZrO2/HZO thin film structure, and an upper or lower portion of the thin film is formed of the first oxide layer 31 and is Zr-rich and in other portion of the thin film, Hf and Zr are mixed in almost equal proportions. In an HZO thin film, Zr may be more distributed or Hf may be more distributed depending on when the deposition terminates (ends), but, in at least one embodiment, a composition ratio of ZrO2/HZO may be greater than 1 for the entire stack. Also, a total thickness of ZrO2/HZO may be, for example, 0.5 nm to 3 nm, and a thickness of the Zr-rich portion may be 0.2 nm to 1 nm in the cases wherein the second oxide layer 35 is terminated with Zr.

According to the electronic device 10 according to at least one embodiment, the ferroelectric layer 30 may be crystallized to have ferroelectric or antiferroelectric properties. For example, the ferroelectric layer 30 may be crystalized to form a ferroelectric layer or crystalized to form an antiferroelectric layer. The ferroelectric layer may include at least 50% of domains having an orthorhombic crystalline phase, and may include less than 50% of tetragonal crystalline phase, monoclinic, or amorphous domains. The antiferroelectric layer may include at least 50% of domains having a tetragonal crystalline phase, and may include less than 50% of orthorhombic crystalline phase, monoclinic, or amorphous domains. To crystalize the ferroelectric layer 30, heat treatment may be performed before and/or after depositing the electrode layer 50a (e.g., the gate electrode 50). For example, heat treatment may be performed before and/or after the ferroelectric layer 30 is covered by the electrode layer 50a. In at least one embodiment ,the heat treatment may be performed only once (e.g., before or after the electrode layer 50a is formed) or at least two times (e.g., before and after the gate electrode is formed). In at least one embodiment, the heat treatment includes controlling the heating and cooling of the stack to promote the formation of the tetragonal and/or orthorhombic phases. As such, in the electronic device 10 according to at least one embodiment, the ferroelectric layer 30 may be formed to have ferroelectric or antiferroelectric properties through a heat treatment process.

The electrode layer 50a (e.g., the gate electrode 50) may include a metal, a metal nitride, a metal carbide, polysilicon, and/or a 2D conductive material. For example, the metal may include aluminum (Al), tungsten (W), molybdenum (Mo), titanium (Ti), tantalum (Ta), and/or the like; the metal nitride may include titanium nitride (TiN), tantalum nitride (TaN), and/or the like; and/or the metal carbide may be a metal carbide doped with (e.g., containing) aluminum and/or silicon (such as TiAlC, TaAlC, TiSiC, TaSiC, and/or the like). The gate electrode 50 may have a structure in which a plurality of materials are stacked. For example, in at least one embodiment, the gate electrode 50 may have a stacked structure of a metal nitride layer and a metal layer such as TiN/Al and/or a stacked structure of a metal nitride layer, a metal carbide layer, and a metal layer such as TiN/TiAlC/W.

Also, in the electronic device 10 according to at least one embodiment, the gate insulating film 20 may further include a dielectric layer 25 that is not ferroelectric, between the channel 11 and the ferroelectric layer 30. The dielectric layer 25 may include, for example, crystalline and/or amorphous states, and may be a paraelectric layer, a high-k dielectric layer, and/or an antiferroelectric layer. The dielectric layer 25 may be provided between the ferroelectric layer 30 and the gate electrode 50, and/or may be provided between the ferroelectric layer 30 and the gate electrode 50, respectively.

In at least one embodiment, the dielectric layer 25 stabilizes a ferroelectric of the ferroelectric layer 30 in a negative capacitance state. The dielectric layer 25 may include, for example, at least one of SiO, AlO, SiON, and SiN, and may have a single or multi-layer structure.

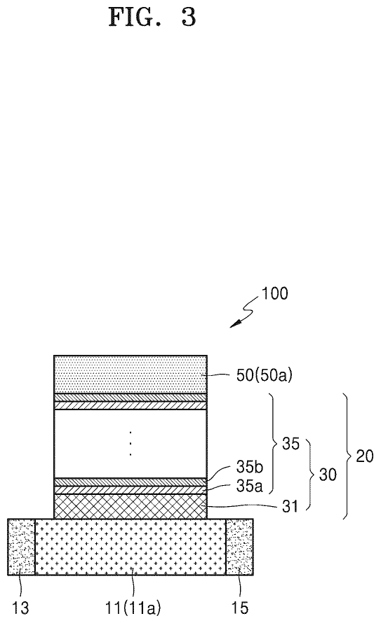

When the channel 11 includes Si or Ge, the dielectric layer 25 may be formed as, for example, a native oxide film, or an oxide layer other than a native oxide film. In another embodiment, even when the channel 11 includes Si or Ge, a native oxide film may be removed, and as in an electronic device 100 of FIG. 3 described below, the ferroelectric layer 30 may be directly formed on the channel 11.

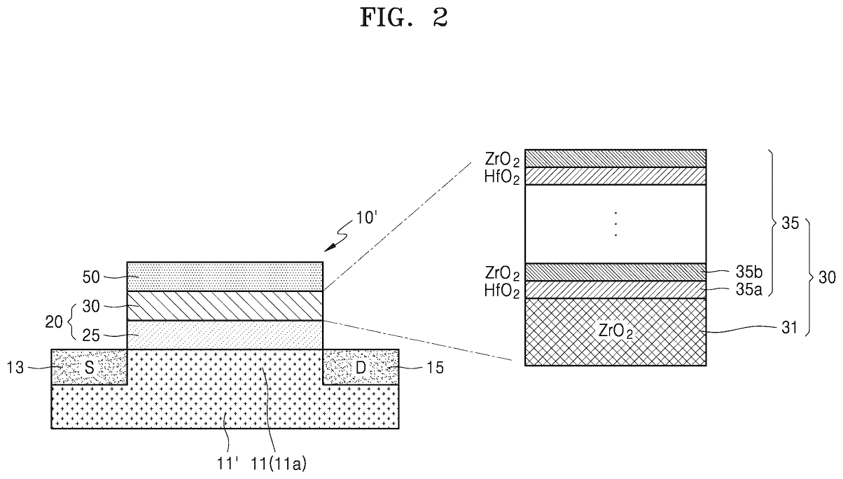

FIG. 2 is a view schematically illustrating an electronic device 10′, according to at least one embodiment and corresponds to an example in which the channel 11 is formed using a semiconductor substrate 11′ as a base in the electronic device 10 of FIG. 1. As shown in FIG. 2, when the channel 11 is formed using the semiconductor substrate 11′ as a base, the first source/drain region 13, the second source/drain region 15, and the channel 11 may be formed by injecting impurities into different regions of the semiconductor substrate 11′.

FIG. 3 is a cross-sectional view schematically illustrating the electronic device 100, according to at least one embodiment. Compared to the electronic device 10 of FIG. 1, the ferroelectric layer 30 is formed directly on the channel 11, and the other elements are substantially the same. As such, the electronic device 100 according to at least one embodiment may not include a dielectric layer (25 in FIG. 1) between the channel 11 and the ferroelectric layer 30.

For example, in the electronic device 100 according to at least one embodiment, the channel 11 may be formed using a substrate as a base, or may be implemented as a separate material layer, as described above. Also in this case, the ferroelectric layer 30 may be formed on the channel 11 after a native oxide layer formed on the channel 11 is removed.

In the electronic device 100 according to at least one embodiment, when the channel 11 is formed using the semiconductor substrate 11′ (of FIG. 2) as a base, the first source/drain region 13, the second source/drain region 15, and the channel 11 may be formed by injecting impurities into different regions of the semiconductor substrate 11′, like in the electronic device 10′ of FIG. 2.

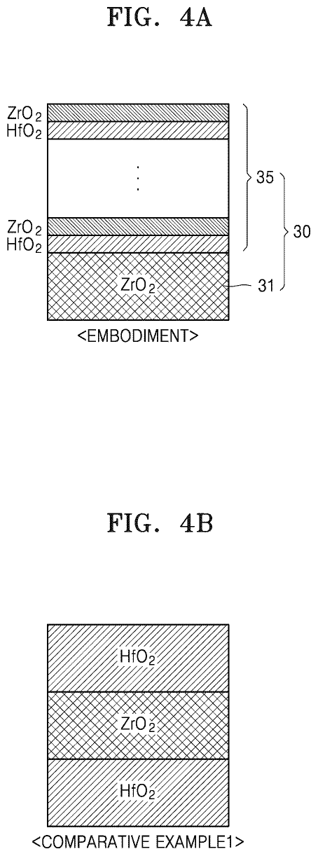

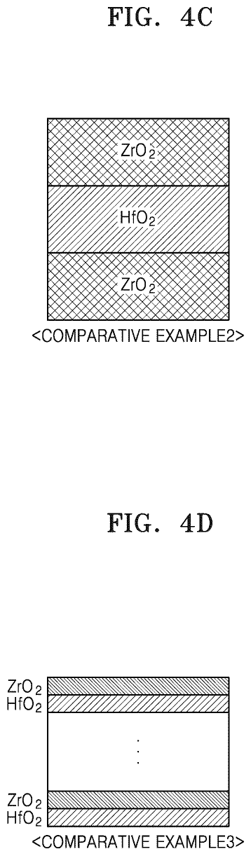

FIG. 4A is a view illustrating a thin film structure of the ferroelectric layer 30 of the electronic device 10 or 100, according to at least one embodiment. FIGS. 4B to 4D are views illustrating thin film structures of comparative example 1, comparative example 2, and comparative example 3.

In FIG. 4A, the ferroelectric layer 30 has a Z/HZO structure including the first oxide layer 31 formed of ZrO2, and the second oxide layer 35 formed using a solid solution deposition method of alternately depositing the HfO2 layer 35a and the ZrO2 layer 35b. In FIG. 4B, a ferroelectric thin film structure of comparative example 1 is a laminate structure, that is, a HZH structure in which an HfO2 layer, a ZrO2 layer, and an HfO2 layer are stacked. In FIG. 4C, a ferroelectric thin film structure of comparative example 2 is a laminate structure, that is, a ZHZ structure in which a ZrO2 layer, an HfO2 layer, and a ZrO2 layer are stacked. In FIGS. 4B and 4C, each of the HfO2 layer and the ZrO2 layer may correspond to the first oxide layer 31 of the ferroelectric layer 30 according to at least some embodiments. That is, comparative example 1 and comparative example 2 may correspond to a structure in which an oxide layer the same as or substantially similar to the first oxide layer 31 is stacked in three layers, and one layer is formed of HfO2 and an adjacent layer is a ZrO2 layer. In FIG. 4D, a ferroelectric thin film structure of comparative example 3 is an HZO structure in which an HfO2 layer and a ZrO2 layer are repeatedly stacked to correspond to the second oxide layer 35 of the ferroelectric layer 30 according to at least one embodiment.

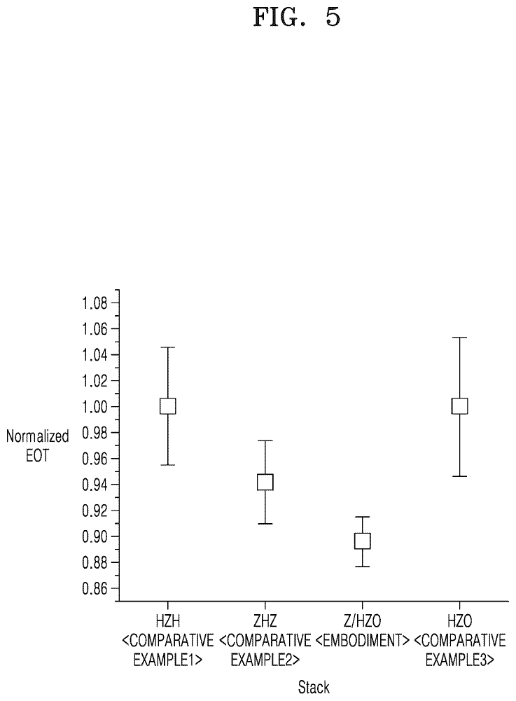

FIG. 5 is a diagram illustrating an equivalent oxide thickness (EOT) change for each ferroelectric thin film structure. In a metal-ferroelectric-insulator-silicon (MOSCAP) structure to which ferroelectric thin film structures of the embodiment of FIG. 4A, comparative example 1 of FIG. 4B, comparative example 2 of FIG. 4, and comparative example 3 of FIG. 4D are applied, when a ferroelectric layer is formed to a thickness of about 2.2 nm. FIG. 5 illustrates a result of normalizing an EOT change for each ferroelectric thin film structure to an EOT value obtained from the HZO-based MOSCAP.

As illustrated in FIG. 5, when the ferroelectric layer 30 is formed as a single film/solid solution laminate Z/HZO thin film structure by combining a single film layer with a solid solution layer formed by using a solid solution deposition method as in the embodiment, an EOT is lower (e.g., about 9%) then a case where a laminate is formed of only a single film layer as in comparative examples 1 and 2 or is formed of only a solid solution layer formed by using a solid solution deposition method as in comparative example 3, and thus, there is an EOT improvement effect. Because an EOT may decrease as a negative capacitance effect of a ferroelectric electronic device increases, when the ferroelectric layer 30 is formed as in the electronic device 10, 10′, or 100 according to at least one embodiment, a device with an increased negative capacitance effect may be implemented.

Although the electronic device 10, 10′, or 100 according to at least one embodiment is described above as a field-effect transistor having the channel 11 that is flat, the examples are not limited thereto. For example, the concept according to the above embodiment may be applied to a FinFET, a gate-all-around FET (GAAFET), a multi-bridge channel FET (MBCFET), and/or the like having a three-dimensional (3D) channel structure.

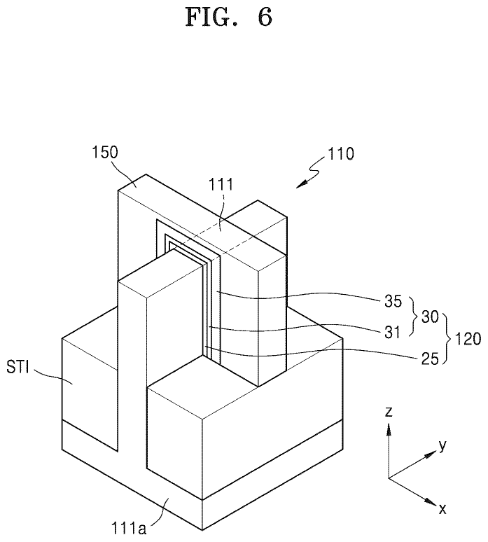

FIG. 6 is a view illustrating an example of an electronic device 110 having a 3D structure including a Fin channel 111, according to at least one embodiment.

Referring to FIG. 6, the electronic device 110 according to at least one embodiment may include the Fin channel 111 protruding in a Z-direction from a top surface of a substrate 111a and extending in a Y-direction. A first source/drain region and a second source/drain region protruding in the Z-direction from the top surface of the substrate 111a may be provided on both sides of the Fin channel 111. For example, a first end of the channel 111 may contact the first source/drain region, and a second end of the channel 111 may contact the second source/drain region. The channel 111 may include, for example, a relatively lightly doped p-type semiconductor or a relatively lightly doped n-type semiconductor.

In at least one embodiment, a shallow trench insulator (STI) may be formed to electrically separate the electronic device 110 from an adjacent device and to form a gate electrode 150 surrounding the channel 111. The STI may be formed by forming a shallow trench around the channel 111 or a region corresponding to the channel 111 and filling the trench with an insulating material. The gate electrode 150 may be formed on the STI to surround the channel 111. A gate insulating film 120 may be provided between the channel 111 and the gate electrode 150. For example, the electronic device 110 having a Fin channel structure may be formed by forming the gate insulating film 120 to surround the channel 111 and forming the gate electrode 150 to surround the gate insulating film 120. The gate electrode 150 may be formed to extend in a X direction. The electronic device 110 of FIG. 6 may be, for example, a FinFET.

In the electronic device 110 according to at least one embodiment, the gate insulating film 120 includes the ferroelectric layer 30 including the first oxide layer 31 and the second oxide layer 35. In at least one embodiment, gate insulating film 120 may include the dielectric layer 25 that is not ferroelectric, or may include only the ferroelectric layer 30 including the first oxide layer 31 and the second oxide layer 35, like in the electronic devices 10 and 100 described with reference to FIGS. 1 and 3, respectively. FIG. 6 illustrates the example where the gate insulating film 120 includes the ferroelectric layer 30 (including the first oxide layer 31 and the second oxide layer 35), and the dielectric layer 25 that is not ferroelectric.

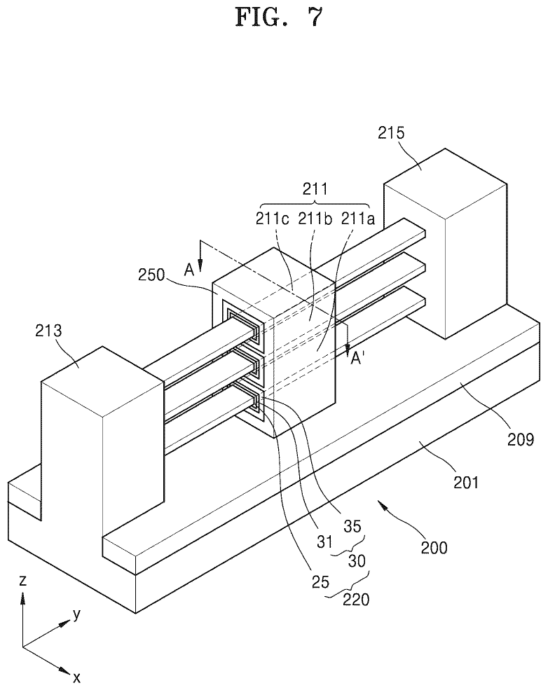

FIG. 7 is a view illustrating an example of an electronic device 200 having a 3D structure in which a gate electrode 250 surrounds the channel 211 in all directions, according to at least one embodiment. FIG. 8 is a cross-sectional view schematically illustrating a gate structure of the electronic device 200 of FIG. 7, in particular, schematically showing a cross-section taken along line A-A′ of the gate structure.

Referring to FIGS. 7 and 8, the electronic device 200 includes a substrate 201, a first source/drain region 213 protruding in the Z-direction from a top surface of the substrate 201, a second source/drain region 215 protruding in the Z-direction from the top surface of the substrate 201, the channel 211 spaced apart from the top surface of the substrate 201 and having a bar shape extending in the Y-direction, a gate insulating film 220 surrounding and covering a region of the channel 211, and a gate electrode 250 surrounding and covering the gate insulating film 220. The channel 211 extends in the Y-direction and may be connect the first source/drain region 213 and the second source/drain region 215. For example, a first end of the channel 211 may contact the first source/drain region 213, and a second end of the channel 211 may contact the second source/drain region 215. The channel 211 may include a relatively lightly doped p-type semiconductor or a relatively lightly doped n-type semiconductor. The channel 211 may include a plurality of channel elements 211a, 211b, and 211c arranged at intervals from each other in an X-direction or the Z-direction. Although, in FIG. 7, three channel elements 211a, 211b, and 211c are arranged at intervals in the Z-direction, this is merely an example, and the examples are not limited thereto. The electronic device 200 of FIG. 7 may be, for example, a GAAFET or an MBCFET.

The electronic device 200 includes a plurality of gate insulating films 220 disposed to respectively surround four surfaces of the plurality of the channel elements 211a, 211b, and 211c. Like in the electronic devices 10 and 100 described with reference to FIGS. 1 and 3, the gate insulating film 220 includes the ferroelectric layer 30 including the first oxide layer 31 and the second oxide layer 35, and may include the dielectric layer 25 that is not ferroelectric, or may include only the ferroelectric layer 30 including the first oxide layer 31 and the second oxide layer 35 and not the dielectric layer 25. FIGS. 7 and 8 illustrate an example where the gate insulating film 220 includes the dielectric layer 25 and the ferroelectric layer 30, and the dielectric layer 25 and the ferroelectric layer 30 are arranged to surround four surfaces of each of the channel elements 211a, 211b, and 211c. The gate electrode 250 may have a structure protruding from a top surface of the substrate 201 and extending in the Z-direction to surround four surfaces of the gate insulating film 220.

The above electronic devices 10, 10′, 100, 110, and 200 may be applied to various electronic apparatuses. For example, the electronic devices 10, 10′, 100, 110, and 200 may be used as logic transistors or memory transistors. Also, the electronic devices 10, 10′, 100, 110, and 200 may be used as memory cells, and may form memory cell array in which a plurality of memory cells may be two-dimensionally arranged, vertically or horizontally arranged, or arranged in one direction to form a memory cell string, and a plurality of memory cell strings may be two-dimensionally and/or three-dimensionally arranged. Also, the electronic devices being above-described may form a part of an electronic circuit constituting an electronic apparatus together with other circuit elements such as capacitors.

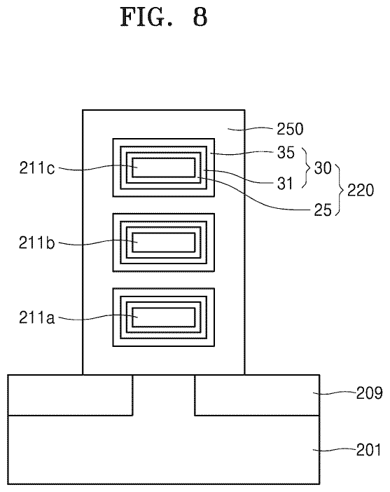

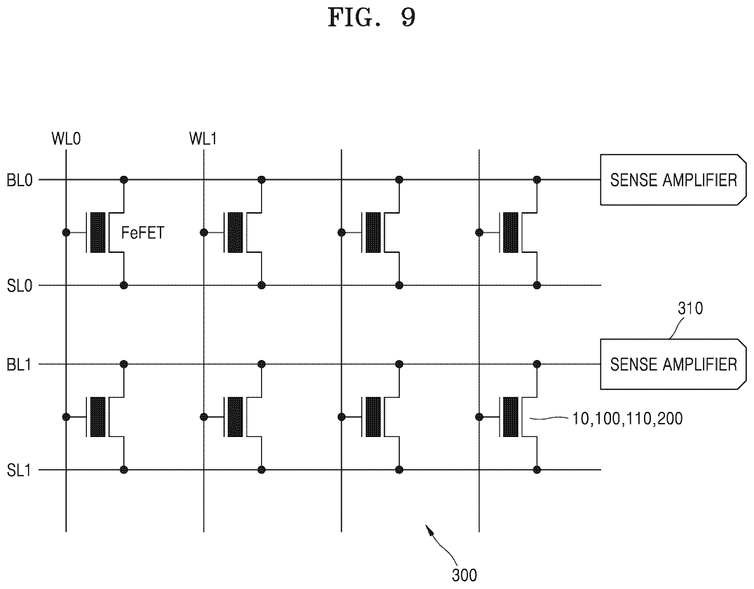

FIG. 9 is a schematic circuit diagram illustrating a memory device including an electronic device array. Referring to FIG. 9, a memory device 300 may include an array of electronic devices 10, 10′, 100, 110, and/or 200 that are two-dimensionally arranged. Also, the memory device 300 may include a plurality of bit lines BL0 and BL1, a plurality of selection lines SL0 and SL1, and a plurality of word lines WL0 and WL1. The selection lines SL0 and SL1 may be electrically connected to a first source/drain region of the electronic device 10, 10′, 100, 110, or 200, the bit lines BL0 and BL1 may be electrically connected to a second source/drain region of the electronic device 10, 10′, 100, 110, or 200, and the plurality of word lines WL0 and WL1 may be electrically connected to a gate electrode of the electronic device 10, 10′, 100, 110, or 200. Also, the memory device 300 may further include an amplifier 310 for amplifying signals output from the bit lines BL0 and BL1. Each of the electronic devices 10, 10′, 100, 110, or 200 may be one memory cell of the memory device 300.

Although FIG. 9 is a 2D plan view for convenience, the memory device 300 may have a structure in which two or more layers are stacked. For example, the plurality of bit lines BL0 and BL1 and the plurality of selection lines SL0 and SL1 that vertically extend may be two-dimensionally arranged, and the plurality of word lines WL0 and WL1 that horizontally extend may be respectively arranged in a plurality of layers. However, the disclosure is not limited thereto, and memory cells may be three-dimensionally arranged in various ways.

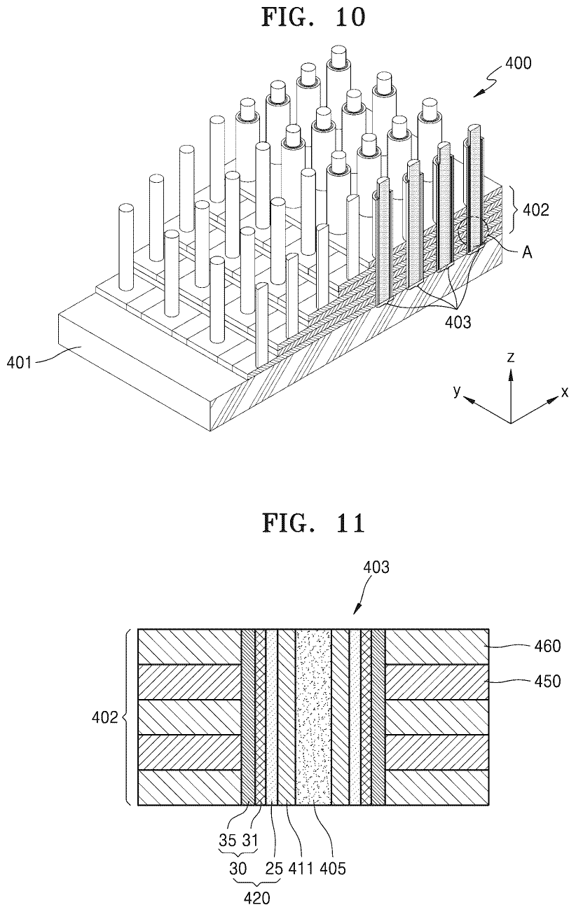

FIG. 10 is a perspective view illustrating an electronic device 400, according to at least one embodiment. FIG. 11 is an enlarged cross-sectional view illustrating a portion ‘A’ of FIG. 10. The electronic device 400 of FIG. 10 may be a memory cell string of a 3D (or vertical) NAND or 3D FeFET memory.

Referring to FIGS. 10 and 11, the electronic device 400 may include a stacked structure 402 in which a plurality of insulating layers 460 and a plurality of gate electrodes 450 are alternately and repeatedly stacked, a plurality of channel holes may be formed to penetrate the stacked structure 402, a gate insulating film 420, a channel 411, and a dielectric filler 405 may be concentrically arranged in the channel holes to form a memory cell string, and a plurality of memory cell strings may be two-dimensionally arranged.

Like in the electronic devices 10 and 100 described with reference to FIGS. 1 and 3, the gate insulating film 420 may include the ferroelectric layer 30 including the first oxide layer 31 and the second oxide layer 35, and the dielectric layer 25 that is not ferroelectric, or may include only the ferroelectric layer 30 including the first oxide layer 31 and the second oxide layer 35 and not the dielectric layer 25. FIGS. 10 and 11 illustrates an example where the gate insulating film 420 includes the dielectric layer 25 and the ferroelectric layer 30.

In detail, the plurality of insulating layers 460 and the plurality of gate electrodes 450 may extend along an X-Y plane on a substrate 401, and may be alternately and repeatedly stacked in the Z-direction to form the stacked structure 402. Also, the electronic device 400 may include a cell string 403 including the gate insulating film 420 including the ferroelectric layer 30 and the dielectric layer 25, the channel 411, and the dielectric filler 405, and the cell string 403 may be disposed to penetrate the stacked structure 402. The insulating layer 460 and the gate electrode 450 may be disposed to surround the periphery of the cell string 403. For example, the gate insulating film 420 including the ferroelectric layer 30 and the dielectric layer 25, the channel 411, and the dielectric filler 405 may extend in the Z-direction and may intersect the insulating layer 460 and the gate electrode 450.

Also, the dielectric filler 405 may be disposed at the center of the cell string 403, and the gate insulating film 420 including the ferroelectric layer 30 and the dielectric layer 25, and the channel 411 may be disposed to concentrically surround the dielectric filler 405. The dielectric layer 25 may be located between the ferroelectric layer 30 and the channel 411. The electronic device 400 may include a plurality of cell strings 403, and the cell strings 403 may be two-dimensionally arranged to be spaced apart from each other on the X-Y plane.

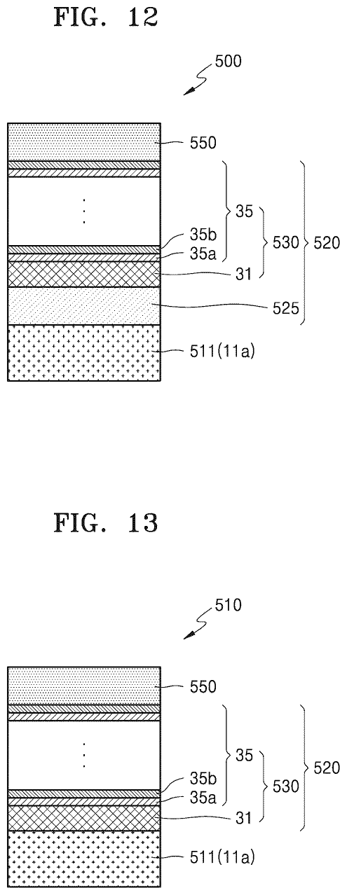

In at least one embodiment, as shown in FIGS. 12 and 13, each of electronic devices 500 and 510 according to at least one embodiment may include an electrode layer 511 as the conductive material layer 11a, and may be implemented as a capacitor. Also, the electronic devices 500 and 510 according to at least one embodiment may be implemented as a capacitor, and may be a part of an electronic circuit implemented as an integrated device.

FIGS. 12 and 13 are cross-sectional views schematically illustrating the electronic devices 500 and 510, according to at least one embodiment.

Referring to FIGS. 12 and 13, each of the electronic devices 500 and 510 according to at least one embodiment may include a first electrode layer 550 and a second electrode layer 511 that are spaced apart from each other and an insulating film 520 disposed between the electrode layer 550 and the electrode layer 511. The electrode layer 511 may correspond to the conductive material layer 11a. The insulating film 520 may include a ferroelectric layer 530 covering the electrode layer 511, and may further include a dielectric layer 525 that is not ferroelectric. The dielectric layer 525 may correspond to the dielectric layer 25 as discussed in reference to FIG. 1. For example, the dielectric layer 525 may include crystalline and/or amorphous states, and may be a paraelectric layer, a high-k dielectric layer, or an antiferroelectric layer. FIG. 12 is a view illustrating an example where the insulating film 520 includes the dielectric layer 525 between the electrode layer 511 and the ferroelectric layer 530, while FIG. 13 is a view illustrating an example where the insulating film 520 includes only the ferroelectric layer 530. The ferroelectric layer of each of the electronic devices 500 and 510 according to at least one embodiment may be provided to have a negative capacitance, and may be implemented as a capacitor or a ferroelectric memory.

Each of the electrode layer 550 and the electrode layer 511 may include a metallically conductive material. For example, each of the electrode layer 550 and the electrode layer 511 may include a metal, an alloy thereof, a metal nitride, a metal carbide, a metal oxide, a 2D conductive material, a combination thereof, and/or the like. For example, the metal may include at least one of aluminum (Al), tungsten (W), molybdenum (Mo), titanium (Ti), tantalum (Ta), chromium (Cr), and copper (Cu), or an alloy thereof; the metal nitride may include, for example, titanium nitride (TiN) or tantalum nitride (TaN); the metal carbide may be a metal carbide doped with (or containing) at least one of aluminum and silicon (for example, TiAlC, TaAlC, TiSiC, or TaSiC); and/or the metal oxide may include, for example, indium oxide (In2O3), tin oxide (SnO2), zinc oxide (ZnO), an indium oxide-tin oxide alloy (In2O3—SnO2: ITO), or an indium oxide-zinc oxide alloy (In2O3-ZnO). At least one of the electrode layer 550 and the electrode layer 511 may include a plurality of layers, and may have, for example, a stacked structure of a metal nitride layer and a metal layer or a stacked structure of a metal nitride layer, a metal carbide layer, a metal layer, and/or the like.

The ferroelectric layer 530 may correspond to the ferroelectric layer 30 of FIGS. 1, 2, and 3, may cover the electrode layer 511, and may include the first oxide layer 31 including a first component and the second oxide layer 35 including hafnium and a second component. The second oxide layer 35 may have a stacked structure in which the hafnium oxide layer 35a and the oxide layer 35b including the second component are alternately and repeatedly stacked, and a surface of the second oxide layer 35 may be terminated with any one of the hafnium oxide layer 35a and the oxide layer 35b including the second component. Each of the first component and the second component may be at least one selected from among Zr, Si, Al, Y, La, Gd, and Sr, and the second component may be the same as or different from the first component. The ferroelectric layer 530 may be the same as and/or substantially similar to the ferroelectric layer 30, and thus, a repeated description will be omitted.

The dielectric layer 525 may include at least one of, for example, SiO, AlO, SiON, and SiN. The dielectric layer 525 may include a plurality of layers having different dielectric constants. The description of the dielectric layer 525 may be the same as or substantially similar to the dielectric layer 25, and thus, a repeated description will be omitted.

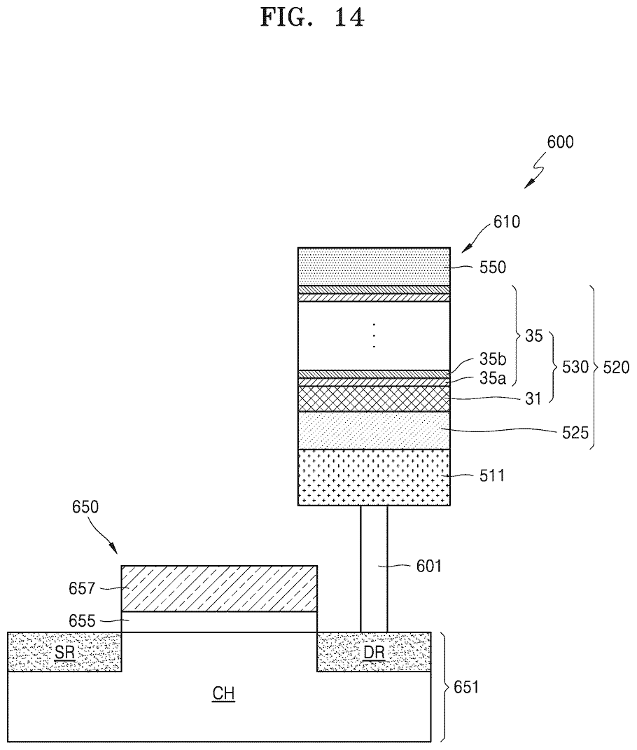

FIG. 14 is a view schematically illustrating an example of applying an electronic device, according to at least one embodiment.

Referring to FIG. 14, an electronic device 600 may have a structure in which a capacitor 610 and a transistor 650 are electrically connected to each other, and may be a part of an electronic circuit implemented as an integrated device.

The electronic device 500 or 510 of FIG. 12 or 13 may be applied to the capacitor 610. The capacitor 610 may have a stacked structure of, for example, the electrode layer 511, the insulating film 520, and the electrode layer 550. The insulating film 520 may include a dielectric layer 525 and a ferroelectric layer 530, or may include only the ferroelectric layer 530 and not the dielectric layer 525. FIG. 14 illustrates an example where the electronic device 500 of FIG. 12 is applied to the capacitor 610.

The capacitor 610 may be electrically connected to the transistor 650 by a contact 601. The transistor 650 may be a field-effect transistor. One of the electrode layers 511 and 550 of the capacitor 610 and one of a source SR and a drain DR of the transistor 650 may be electrically connected by the contact 601.

The transistor 650 may include a semiconductor substrate 651 including the source SR, the drain DR, and a channel CH, a gate electrode 657 facing the channel CH, and a gate insulating layer 655 disposed between the channel CH and the gate electrode 657.

The semiconductor substrate 651 may include a semiconductor material. The semiconductor substrate 651 may include the source SR, the drain DR, and the channel CH electrically connected to the source SR and the drain DR. The source SR may be electrically connected or contact an end of the channel CH, and the drain DR may be electrically connected to or contact the other end of the channel CH. In other words, the channel CH may be defined as a substrate region between the source SR and the drain DR in the semiconductor substrate 651.

The source SR, the drain DR, and the channel CH may be independently formed by injecting impurities into different regions of the semiconductor substrate 651, and in this case, the source SR, the channel CH, and the drain DR may include a substrate material as a base material. Also, the source SR and the drain DR may be formed of a conductive material. The channel CH may not be formed as a substrate base, but may be implemented as a separate material layer.

The gate electrode 657 may be disposed on the semiconductor substrate 651 to be spaced apart from the semiconductor substrate 651 and face the channel CH.

The gate insulating layer 655 may constitute a gate stack together with the gate electrode 657. In at least one embodiment, the gate insulating layer 655 located between the semiconductor substrate 651 and the gate electrode 657 may include a paraelectric material or a high-k dielectric material, but the examples are not limited thereto.

For example, in at least one embodiment, the electronic devices 10, 10′, and 100 described with reference to FIGS. 1, 2, and 3 may be applied to the transistor 650. Also, the transistor 650 may have any of various channel structures, like in the electronic devices 110 and 200 described with reference to FIGS. 6 to 8.

The contact 601 may include an appropriate conductive material, for example, tungsten, copper, aluminum, or polysilicon.

An arrangement of the capacitor 610 and the transistor 650 may be changed in various ways. For example, the capacitor 610 may be disposed over the semiconductor substrate 651 as shown in FIG. 14, or may be buried in the semiconductor substrate 651. In at least one embodiment, the contact 601 may be omitted and the capacitor 610 and the transistor 650 directly connected.

FIG. 14 illustrates the electronic device 600 including one capacitor 610 and one transistor 650, but the examples are not limited thereto, and the electronic device 600 may include two-dimensionally and repeatedly arranged structure thereof.

In an electronic device and an electronic apparatus using the same according to various embodiments, thin film deposition may be performed by using any of various deposition methods such as atomic layer deposition (ALD), metal organic atomic layer deposition (MOALD), chemical vapor deposition (CVD), metal organic chemical vapor deposition (MOCVD), or physical vapor deposition (PVD). Also, doping may be performed by using a method such as light ion implant, plasma treatment, or annealing under specific atmosphere, in addition to the deposition method.

According to an electronic device according to various embodiments, in a MOSCAP structure (including a gate stack) or a capacitor structure in which a ferroelectric layer including a first oxide layer including a first component and a second oxide layer including hafnium and a second component, and a dielectric layer that is not ferroelectric are stacked, an overall EOT may be lower than an EOT of a CAP structure including a remaining dielectric layer excluding the ferroelectric layer and an electrode/channel material. Also, an electronic device according to various embodiments may have a MOSCAP structure or a capacitor structure in which a ferroelectric layer including a first oxide layer and a second oxide layer and a dielectric layer that is not ferroelectric are stacked, may be used as a gate stack when applied to a field-effect transistor FET, and may be applied in a 3D structure as well as a 2D structure.

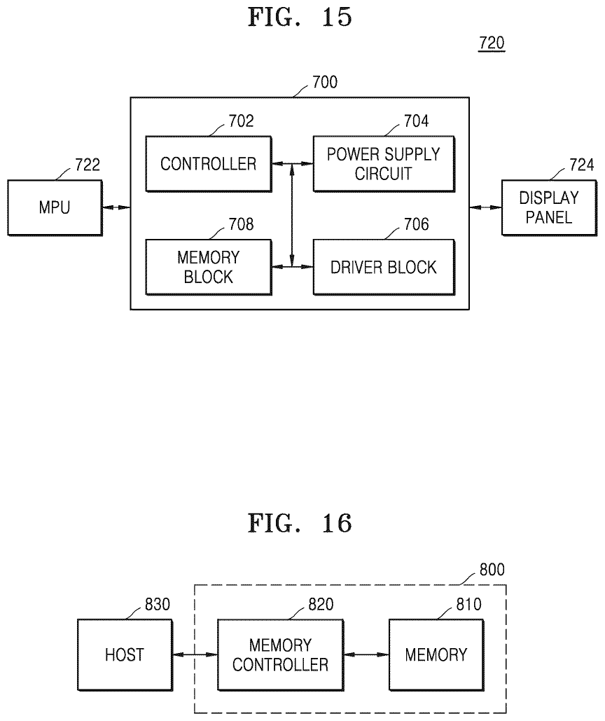

FIG. 15 is a schematic block diagram illustrating a display driver integrated circuit (IC) (DDI) 700 and a display apparatus 720 including the DDI 700, according to at least one embodiment.

Referring to FIG. 15, the DDI 700 may include a controller 702, a power supply circuit 704, a driver block 706, and a memory block 708. The controller 702 receives and decodes a command applied from a main processing unit (MPU) 722, and controls each block of the DDI 700 to implement an operation according to the command. The power supply circuit 704 generates a driving voltage in response to control of the controller 702. The driver block 703 drives a display panel 724 by using the driving voltage generated in the power supply circuit 704 in response to control of the controller 702. The display panel 724 may be, for example, a liquid crystal display panel, an organic light emitting device (OLED) display panel, a micro-light emitting device (μLED) panel, or a plasma display panel. The memory block 708 is a block that temporarily stores a command input to the controller 702 and/or control signals output from the controller 702, or stores necessary data, and may include a memory such as a RAM or a ROM. At least one of the controller 702, the power supply circuit 704, the driver block 706, and/or the memory block 708 may include electronic devices according to the above embodiments. For example, the memory block 708 may include electronic devices according to the above embodiments.

FIG. 16 is a block diagram illustrating an electronic apparatus 800, according to at least one embodiment. Referring to FIG. 16, the electronic apparatus 800 includes a memory 810 and a memory controller 820. The memory controller 820 may control the memory 810 to read data from the memory 810 and/or write data to the memory 810 in response to a request of a host 830. The memory 810 may include electronic devices according to the above embodiments.

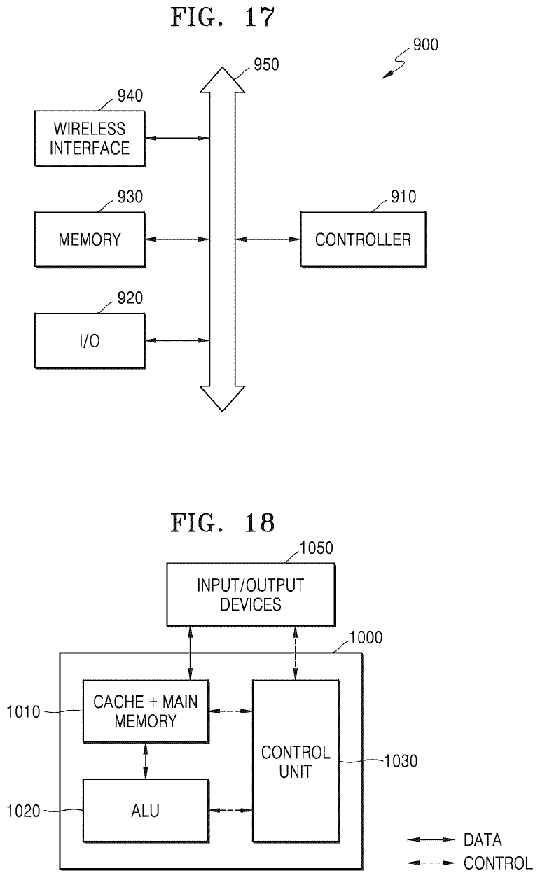

FIG. 17 is a block diagram illustrating an electronic apparatus 900, according to at least one embodiment. Referring to FIG. 17, the electronic apparatus 900 may constitute a wireless communication device and/or a device configured to transmit and/or receive information in a wireless environment. The electronic apparatus 900 may include a controller 910, an input/output device I/O 920, a memory 930, and a wireless interface 940, which may be connected to each other through a bus 950.

The controller 910 may include at least one of a microprocessor, a digital signal processor, or similar processing apparatus thereof. The input/output device 920 may include at least one of an input and/or an output device, such as a keypad, a keyboard, a display, and/or the like. The memory 930 may be used to store a command executed by the controller 910. For example, the memory 930 may be used to store user data. The electronic apparatus 900 may use the wireless interface 940 to transmit/receive data through a wireless communication network. The wireless interface 940 may include an antenna and/or a wireless transceiver. In some embodiments, the electronic apparatus 900 may be used for a communication interface protocol of a third generation communication system, for example, code division multiple access (CDMA), global system for mobile communications (GSM), North American digital cellular (NADC), extended-time division multiple access (E-TDMA), and/or wide band code division multiple access (WCDMA). The memory 930 of the electronic apparatus 900 may include an electronic device according to the above embodiments.

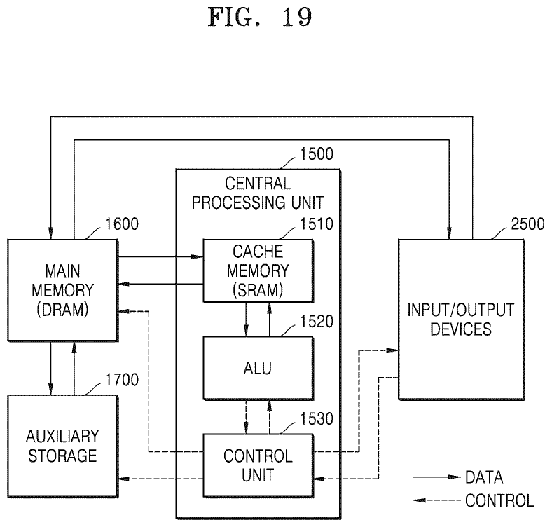

FIGS. 18 and 19 are conceptual diagrams schematically illustrating a device architecture applicable to an electronic apparatus, according to at least some embodiments.

Referring to FIG. 18, an electronic device architecture 1000 may include a memory unit 1010 and a control unit 1030, and may further include an arithmetic logic unit (ALU) 1020. The memory unit 1010, the ALU 1020, and the control unit 1030 may be electrically connected to each other. In at least one embodiment, the electronic device architecture 1000 may be implemented as one chip including the memory unit 1010, the ALU 1020, and the control unit 1030. For example, the memory unit 1010, the ALU 1020, and the control unit 1030 may be connected to each other via a metal line on-chip to directly communicate with each other. The memory unit 1010, the ALU 1020, and the control unit 1030 may be monolithically integrated on one substrate to constitute one chip. An input/output device 1050 may be connected to the electronic device architecture (chip) 1000. Also, the memory unit 1010 may include both a main memory and a cache memory. The electronic device architecture (chip) 1000 may be an on-chip memory processing unit. The memory unit 1010, the ALU 1020, and/or the control unit 1030 may independently include an electronic device according to the above embodiments.

Referring to FIG. 19, a cache memory 1510, an ALU 1520, and a control unit 1530 may constitute a central processing unit (CPU) 1500, and the cache memory 1510 may include, for example, a static random-access memory (SRAM). Apart from the CPU 1500, a main memory 1600 and an auxiliary storage 1700 may be provided, and an input/output device 2500 may be provided. The main memory 1600 may be, for example, a dynamic random-access memory (DRAM), and may include an electronic device according to the above embodiments.

In some cases, an electronic device architecture may be implemented so that computing unit devices and memory unit devices are adjacent to each other in one chip, without distinguishing sub-units.

In an electronic device, according to at least one embodiment, because a ferroelectric layer has a laminate structure including a first oxide layer and a second oxide layer, wherein the first oxide layer is a single film layer including a first component and the second oxide layer is a solid solution layer including hafnium and a second component, compared to a case where a ferroelectric layer includes only a single film layer or only a solid solution layer, an EOT may be reduced, and thus a negative capacitance effect may be enhanced.

It should be understood that the embodiments described herein should be considered in a descriptive sense only and not for purposes of limitation. Descriptions of features or aspects within each embodiment should typically be considered as available for other similar features or aspects in other embodiments. While some embodiments have been described with reference to the figures, it will be understood by one of ordinary skill in the art that various changes in form and details may be made therein without departing from the spirit and scope as defined by the following claims.

What is claimed is:

1. An electronic device comprising:
a conductive material layer;
a ferroelectric layer covering the conductive material layer and having ferroelectric or antiferroelectric properties; and
an electrode layer covering the ferroelectric layer,
wherein the ferroelectric layer comprises
a first oxide layer comprising a first component and having a first thickness, and
a second oxide layer comprising hafnium and a second component and having a second thickness that is twice or more the first thickness.

2. The electronic device of claim 1, wherein a ratio of the second thickness to the first thickness is 2:1 to 10:1.

3. The electronic device of claim 1, wherein
the first thickness is 1 nm or less, and
a total thickness of the ferroelectric layer is 3 nm or less.

4. The electronic device of claim 3, wherein
the first thickness is 0.2 nm to 1 nm, and
the total thickness of the ferroelectric layer is 0.5 nm to 3 nm.

5. The electronic device of claim 1, wherein a proportion of the second component is greater than a proportion of the hafnium at a surface of the second oxide layer.

6. The electronic device of claim 5, wherein the proportion of the second component is greater than the proportion of the hafnium in a region of the second oxide layer from the surface to a thickness portion of ⅓ or less.

7. The electronic device of claim 5, wherein
the first component and the second component are Zr,
the first oxide layer comprises ZrO2, and
the second oxide layer comprises alternating oxides of Hf and Zr.

8. The electronic device of claim 1, wherein
the second oxide layer comprises alternating oxides of Hf and the second component, and
a proportion of the second component is greater than a proportion of the hafnium at a surface of the second oxide layer.

9. The electronic device of claim 8, wherein the second oxide layer is formed by alternately and repeatedly depositing the hafnium oxide and the oxide of the second component in one cycle or in multiple cycles.

10. The electronic device of claim 1, wherein
the first component and the second component are each at least one of Zr, Si, Al, Y, La, Gd, or Sr.

11. The electronic device of claim 10, wherein
the first component and the second component are the same, and
a composition ratio of an oxide of the first component to an oxide of the hafnium is greater than 1 in the ferroelectric layer.

12. The electronic device of claim 11, wherein
the first oxide layer comprises ZrO2, and
the second oxide layer comprises alternating oxides of the hafnium and Zr.

13. The electronic device of claim 1, wherein
the second oxide layer comprises alternating oxides of the hafnium and the second component, and
wherein a surface of the second oxide layer is terminated with an oxide of one of the oxide or the second component.

14. The electronic device of claim 1, wherein
layers are stacked in an order of the first oxide layer, the second oxide layer, and the electrode layer, or an order of the second oxide layer, the first oxide layer, and the electrode layer, and
ferroelectric crystallization of the ferroelectric layer is a result of heat treatment performed before and/or after the electrode layer is formed.

15. The electronic device of claim 1, further comprising:
a dielectric layer, that is not ferroelectric, between at least one of the conductive material layer and the ferroelectric layer or the ferroelectric layer and the electrode layer.

16. The electronic device of claim 1, wherein
the conductive material layer comprises a channel,
the electrode layer comprises a gate electrode, and
the electronic device is at least one of a logic or memory device.

17. The electronic device of claim 16, wherein
the electronic device is at least one of a fin field-effect transistor (FinFET), a gate-all-around FET (GAAFET), or a multi-bridge channel FET (MBCFET),
the electronic device further comprises a substrate, and
the channel comprises a plurality of channel elements extending in a first direction and are least one of spaced apart from a top surface of the substrate or arranged at intervals from each other in a second direction different from the first direction.

18. The electronic device of claim 17, wherein
the ferroelectric layer is one of a plurality of the ferroelectric layers respectively surrounding the plurality of channel elements, and
the gate electrode protrudes from the top surface of the substrate to surround the plurality of the ferroelectric layers.

19. The electronic device of claim 16, comprising
a stacked structure in which a plurality of insulating layers and a plurality of the gate electrodes are alternately stacked,
wherein the electronic device further comprises a plurality of channel holes vertically penetrating the stacked structure,
wherein the ferroelectric layer and the conductive material layer are concentrically arranged in each of the plurality of channel holes.

20. An electronic apparatus comprising at least one electronic device, the at least one electronic device comprises:
a conductive material layer;
a ferroelectric layer covering the conductive material layer and having ferroelectric or antiferroelectric properties; and
an electrode layer covering the ferroelectric layer, wherein the ferroelectric layer comprises
a first oxide layer comprising a first component, and
a second oxide layer comprising hafnium and a second component.
